(19) United States
(12) Patent Application Publication
(10) Pub. No.: US 2025/0254759 A1
(43) Pub. Date: Aug. 7, 2025

(54) LENS HEATING DEVICE FOR A VEHICLE LAMP

(71) Applicant: MIN HSIANG CORPORATION, Tainan City (TW)

(72) Inventor: Jui-Hung, Hung, Kaohsiung City (TW)

(21) Appl. No.: 18/433,038

(22) Filed: Feb. 5, 2024

(51) Int. Cl. H05B 1/02; F21V 29/90; H05B 3/84

(52) U.S. Cl. CPC H05B 1/0236; F21V 29/90; H05B 3/84; H05B 2214/02

(57) ABSTRACT

A lens heating device for a vehicle lamp comprises a lens, at least one electrical connecting member, and an electrically conductive layer. The lens includes a first outer surface and a first inner surface opposite to the first outer surface. The first inner surface includes at least one recessed portion having a bottom face. The at least one electrical connecting member includes a connecting portion disposed in the at least one recessed portion. The connecting portion includes a second outer surface and a second inner surface opposite to the second outer surface. The second inner surface includes an electrical connection face. The electrical connection face is contiguous to and substantially flush with the first inner surface. The electrically conductive layer is disposed on the first inner surface and the electrical connection face and is configured to generate heat.

### BACKGROUND OF THE INVENTION

The present invention relates to a lens heating device for a vehicle lamp and, more particularly, to a lens heating device permitting stable coupling and electrical conduction.

Vehicle lamps generally include headlamps, tail lamps, turn signals, fog lamps, etc. to provide illumination or alarm effects. However, snow may accumulate on the surface of the lens of a vehicle lamp when it snows and, thus, blocks the output light rays. To solve this problem, a heating structure is provided to the lens of the vehicle lamp.

The heating structure generally includes a heating element which is substantially rectilinearly disposed on the lens of the vehicle lamp. The heating element may be electrically conductive metal coating, copper, transparent electrically conductive oxide. Currently, the heating element is rectilinearly disposed on a soft, transparent film which is then displaced in a mold for producing the lens. Molten plastic material for forming the lens is filled into the mold to integrally couple with the transparent film after molding. Therefore, when it snows, the heating element may be energized to heat and melt the snow accumulated on the outer surface of the lens.

However, during molding in the above manufacturing process, the molten plastic material impacts the transparent film and, thus, tends to cause distortion or displacement of the transparent film, resulting in a high defective rate.

U.S. Pat. No. 6,103,998 discloses a resin window for a vehicle. The resin window comprises a resin panel on which a resin film, a conductor, a metal film, and a terminal are disposed. The conductor is provided on the resin film by printing. The resin film is bonded to the inner surface of the resin panel, and the conductor abuts the resin panel. An opening is formed in the resin film. The metal film is disposed to fill the opening and to contact with the conductor. The terminal is laid on the metal film and is electrically connected to the metal film and the conductor. When the terminal is energized, the conductor generates heat to heat the resin panel and perform defogging operation.

The above structure requires a metal film to electrically connect the terminal to the conductor, rendering inconvenient manufacturing. Furthermore, when stable contact cannot be provided between the terminal and the metal film and between the metal film and the conductor, the poor contact will adversely affect the electrical connection. Generally, the conductor heated to 30° C. is enough to perform the defogging operation. However, when applied to a vehicle lamp, a higher temperature is required to melt the snow more rapidly, but the high temperature tends to cause deterioration and falling of the adhesive between the resin film and the resin panel. Thus, the above structure is not suitable for melting snow on the lens of the vehicle lamp.

Furthermore, the terminal may be coupled with the resin panel through molding and may contact with the conductor on an inner side of the resin film to eliminate the metal film. However, this structure, when applied to a vehicle lamp lens, heating of the conductor will cause unstable bonding between the resin film and the resin panel, such that the conductor and the terminal separate from each other, thereby failing to provide stable electrical conduction.

### BRIEF SUMMARY OF THE INVENTION

An objective of the present invention is to provide a heating device permitting stable coupling and electrical conduction as well as heating the lens of a vehicle lamp.

A lens heating device for a vehicle lamp according to the present invention comprises a lens, at least one electrical connecting member, and an electrically conductive layer. The lens includes a first outer surface and a first inner surface opposite to the first outer surface. The first inner surface includes at least one recessed portion having a bottom face. The at least one electrical connecting member includes a connecting portion disposed in the at least one recessed portion. The connecting portion includes a second outer surface and a second inner surface opposite to the second outer surface. The second inner surface includes an electrical connection face. The electrical connection face is contiguous to and substantially flush with the first inner surface. The electrically conductive layer is disposed on the first inner surface and the electrical connection face and is configured to generate heat.

In an example, the at least one electrical connecting member and the lens are integrally coupled with each other through molding.

In an example, the at least one electrical connecting member includes a terminal and a coupling base. The terminal is electrically conductive and includes a first section and a second section connected to and at an angle to the first section. The terminal is coupled with the coupling base, such that an outer side of the coupling base forms the connecting portion, and an inner side of the first section forms the electrical connection face.

In an example, the lens heating device further comprises at least one temperature sensor which is disposed on the coupling base and which is electrically insulated from the terminal.

In an example, the at least one electrical connecting member includes a terminal which is electrically conductive and which includes a first section and a second section connected to and at an angle to the first section. The first section forms the connecting portion. The lens is coupled with the at least one electrical connecting member through molding by a mold having two positioning members located on two opposite ends of the first section. The two positioning members abut and position the first section while the lens is being coupled with the first section through molding.

In an example, the at least one electrical connecting member is a circuit board.

In an example, the at least one electrical connecting member and the lens are heat-bonded with each other by ultrasonic waves, hot gas, hot mold, or infrared rays. The at least one electrical connecting member includes a terminal which is electrically conductive and which includes a first section and a second section connected to and at an angle to the first section. The first section forms the connecting portion.

In an example, the vehicle lamp includes an enclosed space therein, and the electrically conductive layer is exposed to the enclosed space.

Since the electrical connection face is substantially flush with the first inner surface without substantial level difference therebetween, the electrically conductive layer formed on the electrical connection face and the first inner surface is less likely to break to thereby provide better stability in electrical conduction. Furthermore, the electrically conductive layer may be disposed in a proper pattern on the first inner surface of the lens. The electrically conductive layer is not disposed in a conventional approach in which the electrically conductive layer is firstly disposed on a resin film and then bonded to a surface of a lens. Therefore, the electrically conductive layer can be smoothly disposed on the first inner surface of the lens to provide enhanced product consistency.

The present invention will become clearer in light of the following detailed description of illustrative embodiments of this invention described in connection with the drawings.

### DESCRIPTION OF THE DRAWINGS

FIG. 1 is a partial, cross sectional view of a lens heating device for a vehicle lamp of a first embodiment according to the present invention.

FIG. 2 is a schematic, partial, perspective view of the lens heating device of the first embodiment according to the present invention installed on a vehicle lamp.

FIG. 3 is a schematic top view of the lens heating device for a vehicle lamp of the first embodiment according to the present invention.

FIG. 4 is a schematic, partial, cross sectional view illustrating disposition of a lens for a lens heating device for a vehicle lamp of a second embodiment according to the present invention.

FIG. 5 is a partial, cross sectional view of the lens heating device for a vehicle lamp of the second embodiment according to the present invention after molding.

FIG. 6 is a schematic top view of the lens heating device for a vehicle lamp of the second embodiment according to the present invention.

FIG. 7 is a schematic, partial, cross sectional view illustrating disposition of a lens for a lens heating device for a vehicle lamp of a third embodiment according to the present invention.

FIG. 8 is a partial, cross sectional view of the lens heating device for a vehicle lamp of the third embodiment according to the present invention after molding.

FIG. 9 is a schematic top view of the lens heating device for a vehicle lamp of the third embodiment according to the present invention with a temperature sensor.

FIG. 10 is a partial, exploded, perspective view of a lens heating device for a vehicle lamp of a fourth embodiment according to the present invention.

FIG. 11 is a partial, cross sectional view of the lens heating device for a vehicle lamp of the fourth embodiment according to the present invention after assembly.

FIG. 12 is a partial, cross sectional view of the lens heating device for a vehicle lamp of a fifth embodiment according to the present invention after assembly.

### DETAILED DESCRIPTION OF THE INVENTION

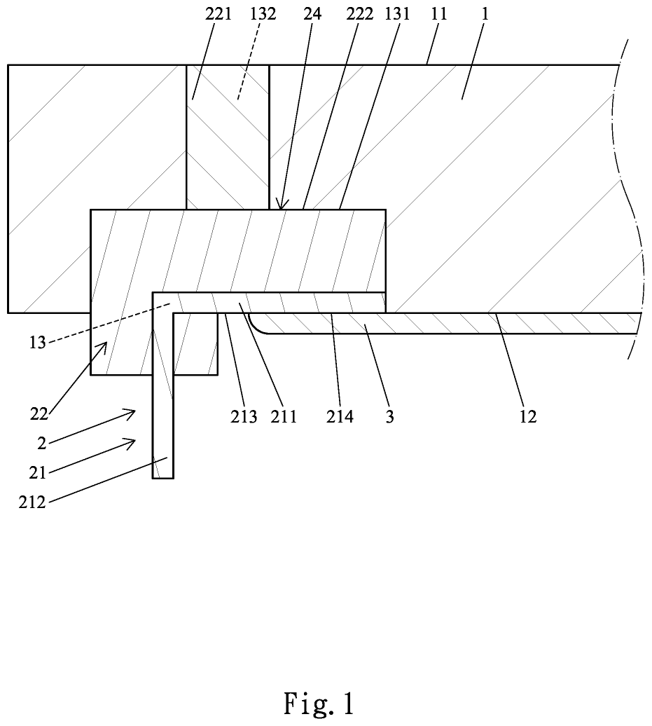

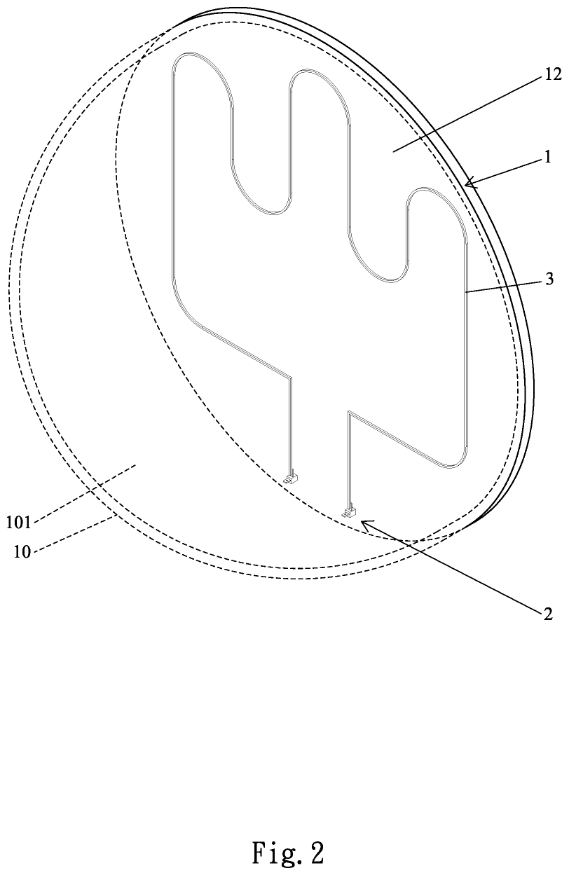

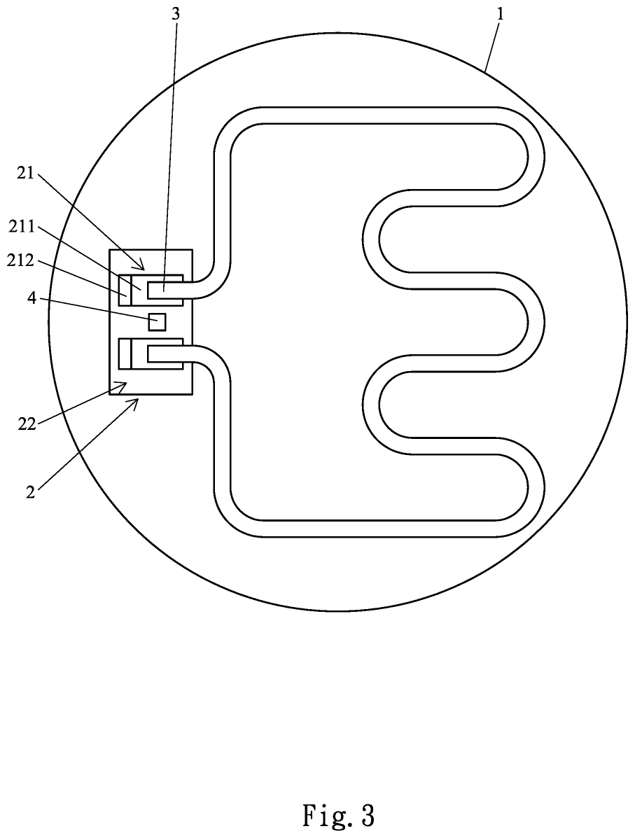

Like elements having similar functions in the following embodiments of the present invention are designated by the same reference numbers. Please refer to FIGS. 1-3 showing a lens heating device for a vehicle lamp of a first embodiment according to the present invention. FIG. 1 is a partial, cross sectional view of the lens heating device for a vehicle lamp according to the present invention. FIG. 2 is a schematic, partial, perspective view illustrating installation of the lens heating device on a vehicle lamp. FIG. 3 is a schematic top view of the lens heating device. The lens heating device for a vehicle lamp of the first embodiment according to the present invention comprises a lens 1, at least one electrical connecting member 2 and an electrically conductive layer 3. The lens 1 is in the form of a cover lens and is disposed on an outer side of a vehicle lamp to cover a housing 10. The lens 1 and the housing 10 have an enclosed space 101 therebetween. Namely, the vehicle lamp includes the enclosed space 101 therein and may receive lighting elements and control members (not shown). The lens 1 includes a first outer surface 11 and a first inner surface 12 opposite to the first outer surface 11. The first inner surface 12 faces the enclosed space 101 and includes at least one recessed portion 13 having a bottom face 131. The bottom face 131 of the at least one recessed portion 13 includes at least one positioning hole 132 extending through the lens 1.

The at least one electrical connecting member 2 includes a connecting portion 24 disposed in the at least one recessed portion 13. The connecting portion 24 includes a second outer surface 222 and a second inner surface 213 opposite to the second outer surface 222. The lens 1 is integrally coupled with the at least one electrical connecting member 2 through injection molding. The at least one electrical connecting member 2 includes a terminal 21 and a coupling base 22. The terminal 21 is electrically conductive and includes a first section 211 and a second section 212 connected to and at an angle to the first section 211. The coupling base 22 and the terminal 21 are firstly coupled with each other through molding, such that an outer side of the coupling base 22 forms the connecting portion 24. The connecting portion 24 further includes at least one protrusion 221. The connecting portion 24 and the at least one recessed portion 13 are coupled with each other through molding, and the at least one protrusion 221 and the at least one positioning hole 132 are coupled with each other through molding. Thus, the lens 1 can be formed stably and can be securely coupled with the at least one electrically connecting member 2. Furthermore, the first section 211 of the terminal 21 includes the second inner surface 213 exposed to an inner side of the coupling base 22, and a portion of the inner side of the first section 211 (i.e., a portion of the second inner surface 213) forms an electrical connection face 214.

The at least one electrical connecting member 2 is placed into a mold (not shown) for forming the lens 1, such that the at least one electrical connecting member 2 is coupled with the lens 1 after molding. Furthermore, the connecting portion 24 of the at least one electrical connecting member 2 may be located in the lens 1. Furthermore, the at least one recessed portion 13 is formed on the lens 1, and the bottom face 131 of the at least one recessed portion 13 can be coupled with the second outer surface 222. Furthermore, the bottom face 131 of the at least one recessed portion 13 includes at least one positioning hole 132 extending through the lens 1 and aligned with the at least one protrusion 221. The at least one protrusion 221 can be coupled with the at least one positioning hole 132 to enhance the coupling stability of the at least one electrical connecting member 2 and the lens 1 through molding. Therefore, in a case that the terminal 21 is directly coupled with the lens 1 through molding, this embodiment may reduce the shift of the terminal 21 caused by the impact from injection of the molten plastic material, thereby enhancing the stability and consistency of the product. After the at least one electrical connecting member 2 is coupled with the lens 1 through molding by a mold (not shown), the electrical connection face 214 can be contiguous to and substantially flush with the first inner surface 12.

The electrically conductive layer 3 is disposed on the first inner surface 12 and the electrical connection face 214 and is configured to generate heat. In this embodiment, the electrically conductive layer 3 is formed on the first inner surface 12 and the electrical connection face 214 through printing. The first inner surface 12 of the lens 1 may be roughened and metalized by laser activation. Furthermore, the electrically conductive layer 3 may be formed on the first inner surface 12 and the electrical connection face 214 by electroplating. In other embodiments, the electrically conductive layer 3 may be formed on the first inner surface 12 and the electrical connection face 214 by sputtering or vapor deposition. Since the electrical connection face 214 is substantially flush with the first inner surface 12 without substantial level difference therebetween, the electrically conductive layer 3 formed on the electrical connection face 214 and the first inner surface 12 is less likely to break to thereby provide better stability in electrical conduction.

The lens heating device according to the present invention may include two electrical connecting members 2 coupled with the lens 1 through molding to form a positive electrode and a negative electrode. Furthermore, the electrically conductive layer 3 may be disposed in a proper pattern on the first inner surface 12 of the lens 1 and may connect with the positive electrode and the negative electrode of the two electrical connecting members 2. The electrically conductive layer 3 is not disposed in a conventional approach in which the electrically conductive layer 3 is firstly disposed on a resin film and then bonded to a surface of a lens, which avoids the problem of failing to provide smooth disposition of the electrically conductive layer 3 on the lens when the resin film has creases. Furthermore, in a case that the lens 1 has a curved shape, the electrically conductive layer 3 can still be smoothly disposed on the first inner surface 12 of the lens 1 to provide better quality in disposition. Furthermore, the electrically conductive layer 3 is exposed to the enclosed space 101 in the vehicle lamp. This may avoid the risk of inadvertent touch by a hand when the electrically conductive layer 3 is heated to a high temperature for melting snow. Furthermore, the electrically conductive layer 3 is prevented from being collided with external wind, rain, and dust during driving, thereby avoiding falling of the electrically conductive layer 3.

With reference to FIG. 3, the lens heating device according to the present invention may further comprise at least temperature sensor 4 disposed on the coupling base 22. The at least one temperature sensor 4 is electrically insulated from the terminal 21. Furthermore, the at least one temperature sensor 4 may be connected to a control device (not shown) to detect the temperature of the lens 1. Since the at least one temperature sensor 4 of this embodiment can be directly disposed on the coupling base 22 rather than the lens 1 or other location. Therefore, the coupling base 22 of this embodiment can provide the at least one temperature sensor 4 with enhanced installation convenience.

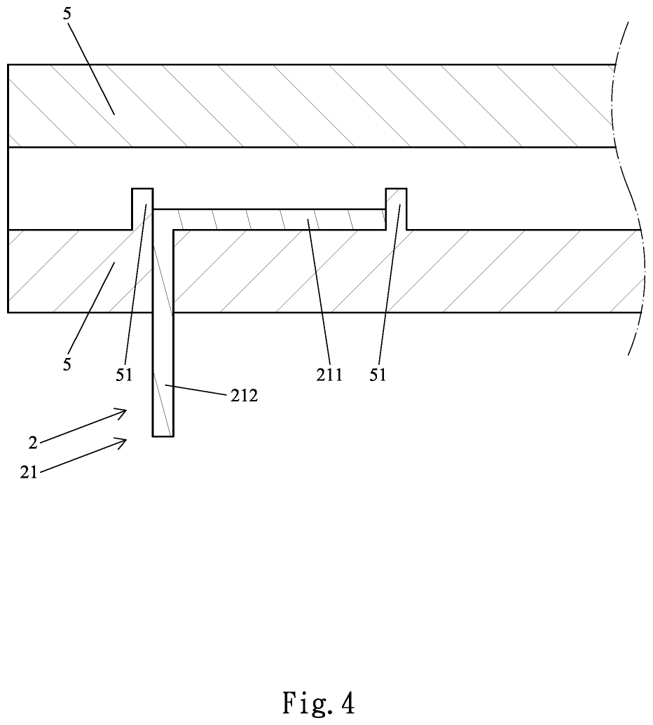

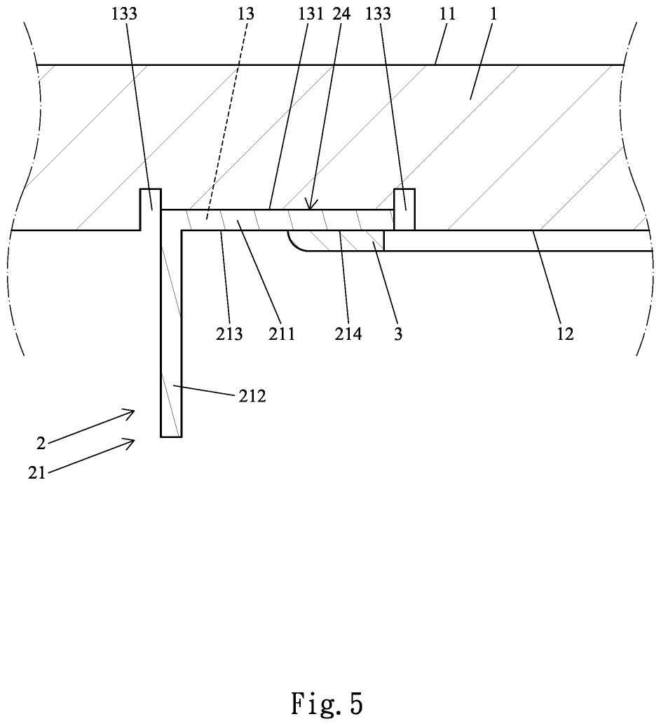

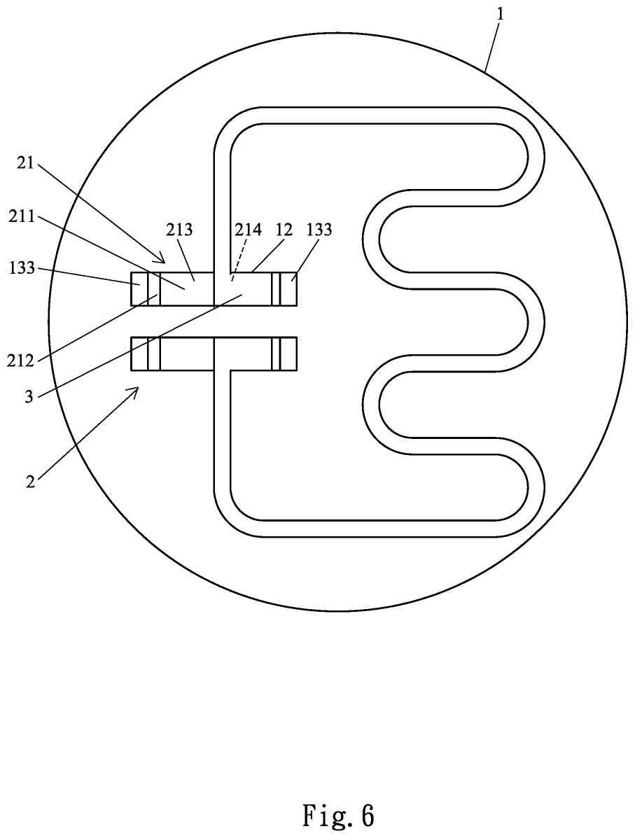

FIGS. 4-6 show a lens heating device of a second embodiment according to the present invention. FIG. 4 is a schematic view illustrating disposition of a lens for the lens heating device for a vehicle lamp. FIG. 5 is a cross sectional view of the lens heating device after molding. FIG. 6 is a schematic top view of the lens heating device. The main difference between the second embodiment and the first embodiment is that the electrical connecting member 2 is an electrically conductive terminal 21 whose first section 211 forms the connecting portion 24, and the coupling base 22 shown in FIG. 1 is not required. As shown in FIG. 4, the lens 1 is coupled with the electrical connecting member 2 through molding by a mold 5. The mold 5 has two positioning members 51 located on two opposite ends of the first section 211. The two positioning members 51 abut and position the first section 211 while the lens 1 is being coupled with the first section 211 through molding. Therefore, as shown in FIGS. 4 and 5, the terminal 21 will not move when molten plastic material of the lens 1 is filled into the mold 5. Furthermore, the first section 211 of the terminal 21 forms the connecting portion 24 of the electrical connecting member 2 to provide stable coupling with the lens 1 through molding, and the electrical connection face 214 can be contiguous to and substantially flush with the first inner surface 12. Furthermore, as shown in FIGS. 5 and 6, although the positioning members 51 cause formation of recesses 133 in the lens 1 after molding, the electrically conductive layer 3 can be coupled with the electrical connection face 214 in a direction other than the direction of the recesses 133, thereby assuring stable electrical connection between the electrically conductive layer 3 and the electrical connection face 214. This embodiment does not require the coupling base 22 in the first embodiment to provide enhanced convenience in manufacture.

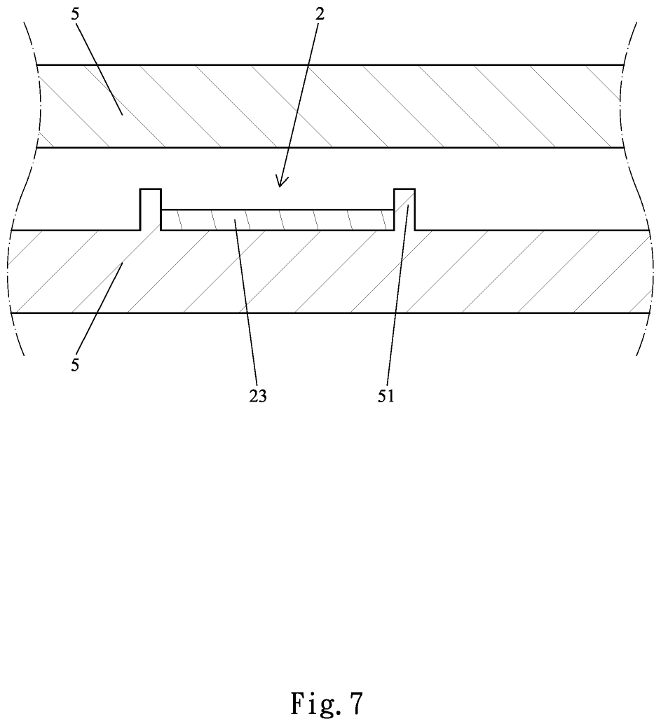

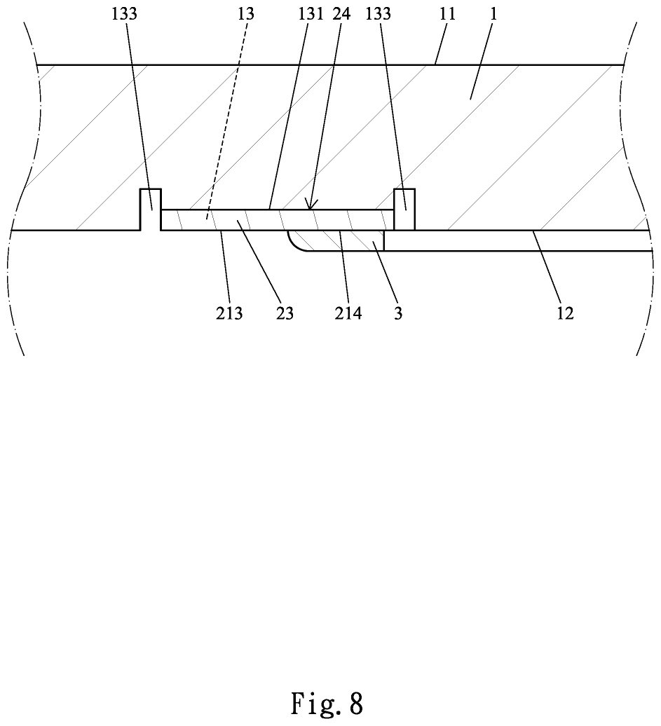

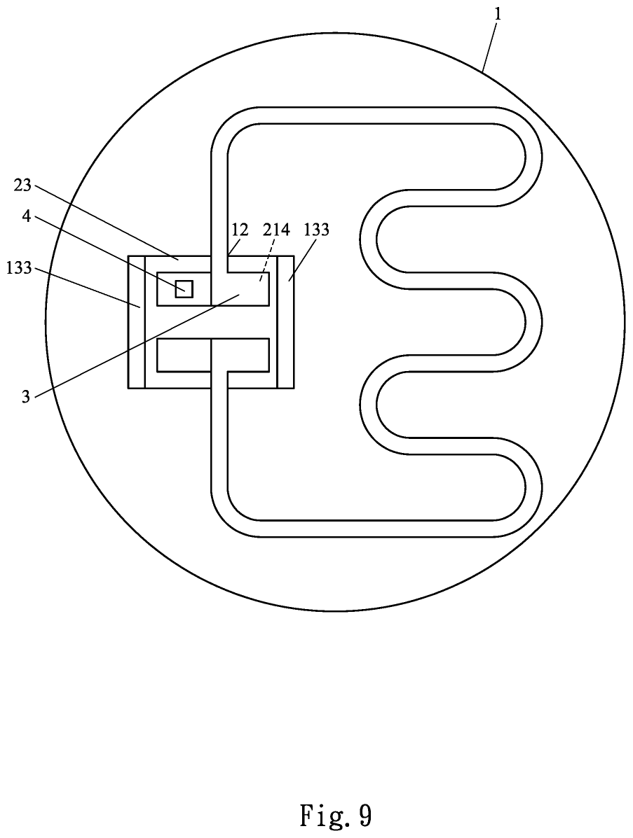

Please refer to FIGS. 7-9 showing a lens heating device of a third embodiment according to the present invention. FIG. 7 is a schematic view illustrating disposition of a lens for the lens heating device for a vehicle lamp. FIG. 8 is a cross sectional view of the lens heating device after molding. FIG. 9 is a schematic top view of the lens heating device. The main difference between the third embodiment and the second embodiment is that the electrical connecting member 2 is a circuit board 23. The mold 5 of this embodiment includes two positioning members 51 disposed on two opposite ends of the circuit board 23. Furthermore, as shown in FIGS. 8 and 9, when the circuit board 23 is coupled with the lens 1 through molding, the two positioning members 51 abut and position the circuit board 23. Furthermore, the circuit board 23 forming the connecting portion 24 of the electrical connecting member 2 is securely disposed in the recessed portion 13 of the lens 1. Furthermore, the electrical connection face 214 may be contiguous to and flush with the first inner surface 12. Although the lens 1 includes the recess 133, the electrically conductive layer 3 may be securely connected to the electrical connection face 214 in a direction other than the direction of the recess 133. Furthermore, a temperature sensor 4 may be disposed on the circuit board 23 rather than the lens 1 or other location. Therefore, the circuit board 23 of this embodiment can provide more convenient installation for the temperature sensor 4 which is electrically insulated from the electrical connection face 214.

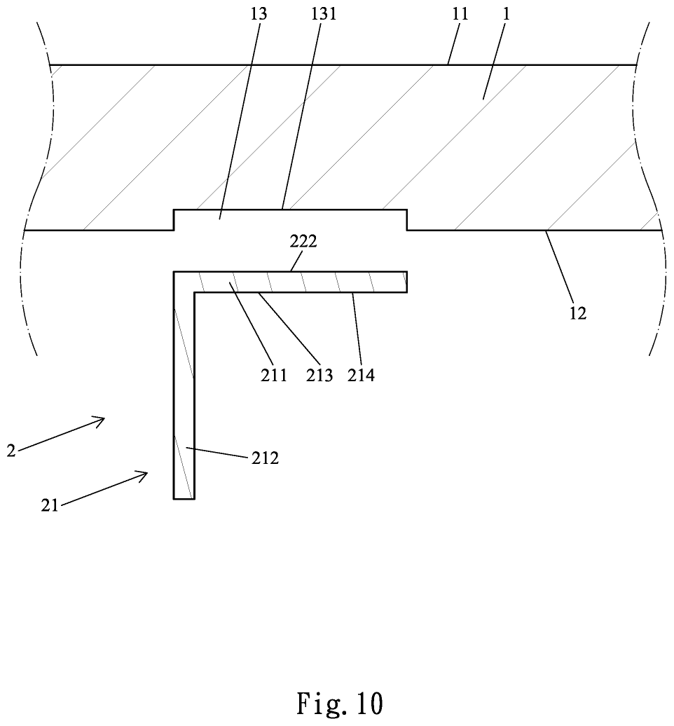

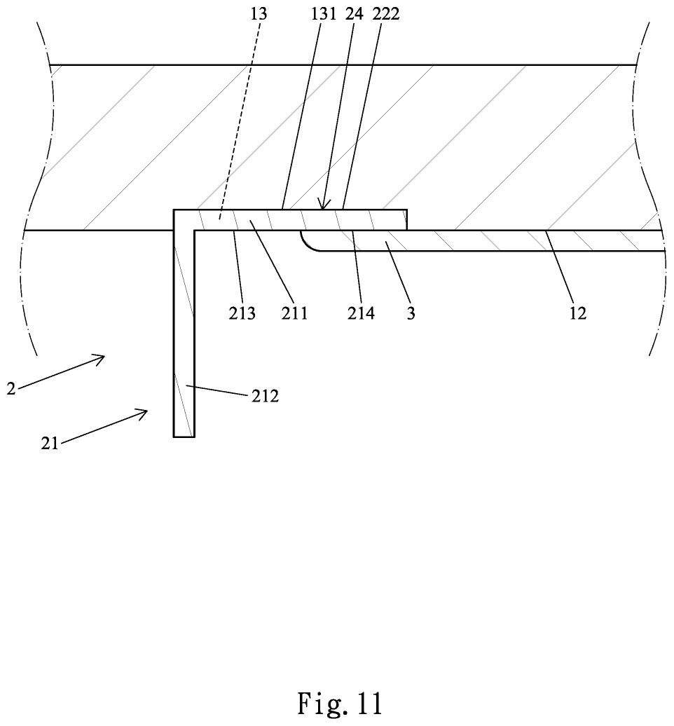

Please refer to FIGS. 10 and 11 showing a lens heating device of a fourth embodiment according to the present invention. FIG. 10 is a schematic partial, exploded view of the lens heating device for a vehicle lamp. FIG. 11 is a partial, cross sectional view of the lens heating device after assembly. As shown in FIG. 10, the main difference between the fourth embodiment and the second embodiment is that the lens 1 is firstly formed and includes a recessed portion 13 (which has a planar shape) on the first inner surface 12. The recessed portion 13 includes the bottom face 131. Namely, the lens 1 has a planar shape in the location of the recessed portion 13, and the connecting portion 24 of the electrical connecting member 2 has a planar shape. Furthermore, the electrical connecting member 2 may be an electrically conductive terminal 21 whose first section 211 has a planar shape and forms the connecting portion 24 of the electrical connecting member 2. Furthermore, as shown in FIG. 11, the second outer surface 222 of the first section 211 of the terminal 21 and the bottom face 131 of the recessed portion 13 of the lens 1 may be heat-bonded with each other by ultrasonic waves, hot gas, hot mold, or infrared rays. Furthermore, the electrical connection face 214 is contiguous to and flush with the first inner surface 12. Furthermore, the electrically conductive layer 3 can be securely disposed on the first inner surface 12 and the electrical connection face 214.

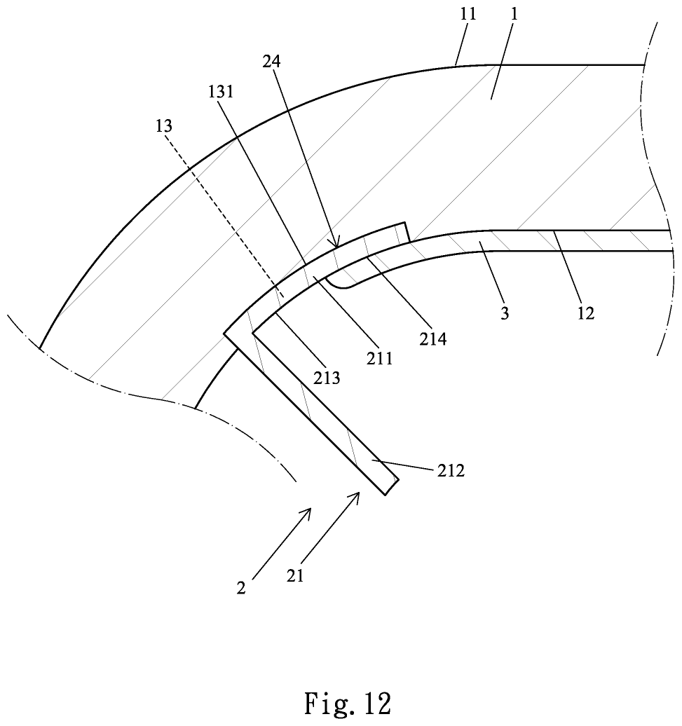

Please refer to FIG. 12 showing a lens heating device for a vehicle lamp of a fifth embodiment according to the present invention. FIG. 12 is a partial, cross sectional view of the lens heating device. The main difference between the fifth embodiment and the fourth embodiment is that the recessed portion 13 of the lens 1 has a curved shape, and the connecting portion 24 of the electrical connecting member 2 has a curved shape. Furthermore, the electrical connecting member 2 may be an electrically conductive terminal 21 whose first section 211 has a corresponding curved shape. Furthermore, the first section 211 of the terminal 21 and the bottom face 131 of the recessed portion 13 of the lens 1 may be securely heat-bonded with each other. Furthermore, the electrical connection face 214 is contiguous to and substantially flush with the first inner surface 12. Furthermore, the electrically conductive layer 3 can be securely coupled with the curved first inner surface 12 and the curved electrical connection face 214, thereby enhancing the electrical conduction stability.

In view of the foregoing, the present invention can enhance the stability in the coupling, electrical conduction, and manufacturing consistency of the lens heating device for a vehicle lamp. The foregoing embodiments are examples of the present invention, not limitation to the present invention. All equivalent changes made in accordance with the spirit of the present invention should also fall within the scope of the present invention.

1. A lens heating device for a vehicle lamp, comprising:
a lens including a first outer surface and a first inner surface opposite to the first outer surface, wherein the first inner surface includes at least one recessed portion having a bottom face;
at least one electrical connecting member including a connecting portion disposed in the at least one recessed portion, wherein the connecting portion includes a second outer surface and a second inner surface opposite to the second outer surface, wherein the second inner surface includes an electrical connection face, and wherein the electrical connection face is contiguous to and substantially flush with the first inner surface; and
an electrically conductive layer disposed on the first inner surface and the electrical connection face and configured to generate heat.

2. The lens heating device for the vehicle lamp as claimed in claim 1, wherein the at least one electrical connecting member and the lens are integrally coupled with each other through molding.

3. The lens heating device for the vehicle lamp as claimed in claim 2, wherein the at least one electrical connecting member includes a terminal and a coupling base, wherein the terminal is electrically conductive and includes a first section and a second section connected to and at an angle to the first section, wherein the terminal is coupled with the coupling base, such that an outer side of the coupling base forms the connecting portion, and an inner side of the first section forms the electrical connection face.

4. The lens heating device for the vehicle lamp as claimed in claim 3, wherein the bottom face of the at least one recessed portion includes at least one positioning hole extending through the lens, wherein the connecting portion further includes at least one protrusion, wherein the connecting portion and the at least one recessed portion are coupled with each other through molding, and wherein the at least one protrusion and the at least one positioning hole are coupled with each other through molding.

5. The lens heating device for the vehicle lamp as claimed in claim 3, further comprising at least one temperature sensor, wherein the at least one temperature sensor is disposed on the coupling base and is electrically insulated from the terminal.

6. The lens heating device for the vehicle lamp as claimed in claim 2, wherein the at least one electrical connecting member includes a terminal which is electrically conductive and which includes a first section and a second section connected to and at an angle to the first section, and wherein the first section forms the connecting portion.

7. The lens heating device for the vehicle lamp as claimed in claim 6, wherein the lens is coupled with the at least one electrical connecting member through molding by a mold having two positioning members located on two opposite ends of the first section, and wherein the two positioning members abut and position the first section while the lens is being coupled with the first section through molding.

8. The lens heating device for the vehicle lamp as claimed in claim 2, wherein the at least one electrical connecting member is a circuit board.

9. The lens heating device for the vehicle lamp as claimed in claim 8, wherein the lens is coupled with the at least one electrical connecting member through molding by a mold having two positioning members located on two opposite ends of the circuit board, and wherein the two positioning members abut and position the circuit board while the lens is being coupled with the circuit board through molding.

10. The lens heating device for the vehicle lamp as claimed in claim 8, further comprising at least one temperature sensor, wherein the at least one temperature sensor is disposed on the circuit board and is electrically insulated from the electrical connection face.

11. The lens heating device for the vehicle lamp as claimed in claim 1, wherein the at least one electrical connecting member and the lens are heat-bonded with each other by ultrasonic waves, hot gas, hot mold, or infrared rays.

12. The lens heating device for the vehicle lamp as claimed in claim 11, wherein the at least one electrical connecting member includes a terminal which is electrically conductive and which includes a first section and a second section connected to and at an angle to the first section, and wherein the first section forms the connecting portion.

13. The lens heating device for the vehicle lamp as claimed in claim 1, wherein the at least one recessed portion of the lens has a planar shape, and wherein the connecting portion of the at least one electrical connecting member has a planar shape.

14. The lens heating device for the vehicle lamp as claimed in claim 1, wherein the at least one recessed portion of the lens has a curved shape, and wherein the connecting portion of the at least one electrical connecting member has a curved shape.

15. The lens heating device for the vehicle lamp as claimed in claim 1, wherein the electrically conductive layer is formed on the first inner surface and the electrical connection face by printing, electroplating, sputtering, or vapor deposition.

16. The lens heating device for the vehicle lamp as claimed in claim 1, wherein the first inner surface of the lens is roughened and metalized by laser activation, and wherein the electrically conductive layer is formed on the first inner surface and the electrical connection face by electroplating.

17. The lens heating device for the vehicle lamp as claimed in claim 1, wherein the vehicle lamp includes an enclosed space therein, and wherein the electrically conductive layer is exposed to the enclosed space.
